(19) United States
(12) Patent Application Publication
(10) Pub. No.: US 2025/0293042 A1
(43) Pub. Date: Sep. 18, 2025

(54) HARC ETCH CHEMISTRY FOR SEMINCONDUCTORS

(71) Applicant: Tokyo Electron Limited, Tokyo (JP)

(72) Inventors: Michael RAMSEY, Albany, NY (US); Joshua BAILLARGEON, Albany, NY (US); Alec DORFNER, Albany, NY (US); Minjoon PARK, Albany, NY (US)

(73) Assignee: Tokyo Electron Limited, Tokyo (JP)

(21) Appl. No.: 18/607,202

(22) Filed: Mar. 15, 2024

(51) Int. Cl. H01L 21/311; H01L 21/033

(52) U.S. Cl. CPC H01L 21/31116; H01L 21/0332; H01L 21/31144

(57) ABSTRACT

A method for etching wafer includes providing a wafer, forming a mask comprising a pattern on a surface of the wafer, and etching the mask by using an etchant gas. The wafer includes an oxide containing material layer. The mask includes a material at least partially containing a metal. The etchant gas is selected from a group consisting of CF₄, CHF₃, and NF₃. Therefore, increased selectivity between the mask and the wafer and satisfactory etch rate (ER) can be achieved.

### TECHNICAL FIELD

The present application generally relates to the field of etching semiconductor wafers.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

### SUMMARY

As described herein, a method may include providing a wafer, forming a mask including a pattern on a surface of the wafer, and selectively etching the mask and the wafer under the mask by using an etchant gas that is selected from a group consisting of CF₄, CHF₃, and NF₃. The wafer includes an oxide containing material layer. The mask includes a material that is at least partially metallic.

In some embodiments, the oxide containing material layer may include an oxide layer on a nitride layer. In some embodiments, the oxide containing material layer includes a stack of alternate oxide and nitride layers on top of each other. In some embodiments, the at least partially metallic material includes a tungsten containing material. In some embodiments, the tungsten containing material includes tungsten silicide (WSi_{X}).

An etchant for etching a wafer with a mask may include a gas selected from a group consisting of CF₄, CHF₃, and NF₃. The mask includes at least a pattern and is made of a material that is at least partially metallic.

In some embodiments, the wafer includes an oxide containing material layer. In some embodiments, the oxide containing material layer includes an oxide layer on a nitride layer. In some embodiments, wherein the oxide containing material layer includes a stack of alternate oxide and nitride layers on top of each other. In some embodiments, wherein the at least partially metallic material comprises a tungsten containing material. In some embodiments, the tungsten containing material comprises tungsten silicide (WSi_{X}).

In yet another general aspect, a method includes forming a mask including a pattern on a wafer; and selectively etching the mask and the wafer under the mask by using an etchant gas that is selected from a group consisting of CF₄, CHF₃, and NF₃. The mask includes a material that is at least partially metallic.

In some embodiments, the wafer includes an oxide containing material layer. In some embodiments, the oxide containing material layer includes an oxide layer on a top of a nitride layer. In some embodiments, the oxide containing material layer includes a stack of alternate oxide and nitride layers on top of each other. In some embodiments, the at least partially metallic material includes a tungsten containing material. In some embodiments, the tungsten containing material includes tungsten silicide (WSi_{X}). In some embodiments, the etchant gas consists of CF₄. In some embodiments, the etchant gas consists of CHF₃. In some embodiments, the etchant gas consists of NF₃.

Implementations of the described techniques may include hardware, a method or process, or a computer tangible medium for performing the process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view illustrating a wafer that will be etched with a mask by an etchant gas (before etching), according to some embodiments.

FIG. 2 is a cross-sectional view illustrating a wafer that is etched with the mask by the etchant gas (after etching), according to some embodiments.

FIG. 3 illustrates a comparison of an etch of an ONO wafer and an etch of an ONO wafer with an ACL mask using C₄F₆ as an etchant gas, according to some embodiments.

FIG. 4 is a flowchart illustrating a method of etching a wafer with a mask by an etchant gas. according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact. There are also embodiments in which additional features may be formed between the first and second features such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element or feature as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

High aspect ratio contact (HARC) etches are often needed in manufacturing semiconductor devices, such as 3D NAND memories. For example, a HARC etch to a wafer with an amorphous carbon layer (ACL) mask on the wafer may use polymeric fluorocarbon (FC) gases (such as C₄F₆ and C₄F₈) as etchants to attempt to maintain adequate selectivity between the ACL mask and the wafer to obtain demanded high aspect ratios. However, these polymeric FC gases may lead to slower etch rates (ERs) and disadvantageous contact deformations, which can disadvantageously impact device performances, and thus an improved HARC etch chemistry is needed.

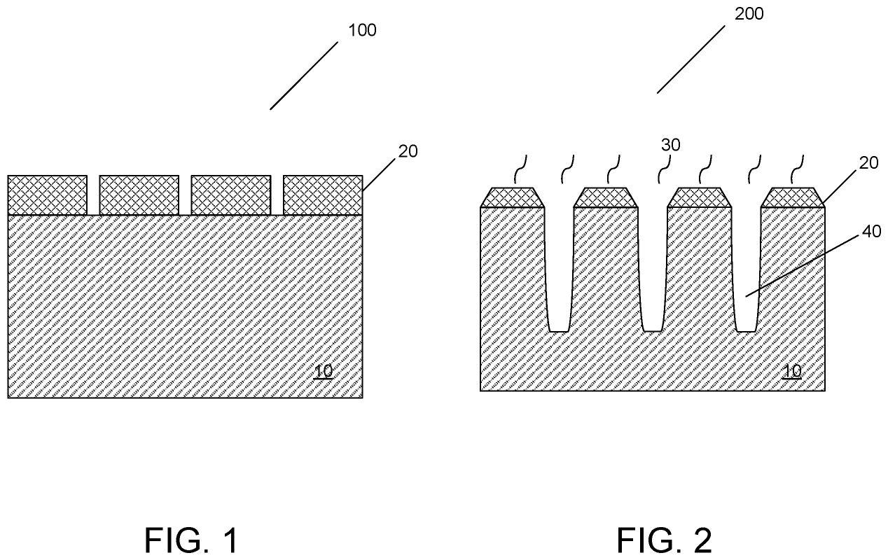

FIG. 1 is a cross-sectional view 100 illustrating a wafer 10 that will be etched with a mask 20 by an etchant gas 30 (before etching) according to some embodiments. In some embodiments, the mask 20 is formed on the wafer 10, before an etching process is performed on the wafer 10.

In some embodiments, the wafer 10 includes an oxide containing material layer. In some embodiments, the oxide containing material layer of the wafer 10 includes an oxide layer on a nitride layer (referred to as “ON” layers), and in other embodiments, the oxide containing material layer of the wafer 10 includes a stack of alternate oxide and nitride layers on top of each other (referred to as “ONO” layers).

In some embodiments, the mask 20 includes one or more patterns such that some regions of a top surface of the wafer 10 are exposed, while other regions of the top surface of the wafer 10 are covered and thus protected by the mask 20. The patterns of the mask 20 can be formed by using, for example, photolithography, etchings (such as wet etchings, or dry etchings by plasmas), and (chemical mechanical polishing) CMP processes, etc.

In some embodiments, the mask 20 is a hard mask, which includes a material at least partially containing metal. In some embodiments, the at least partially metallic material of the mask 20 includes a tungsten (W) containing material. In some embodiments, the tungsten containing material of the mask 20 includes tungsten silicide (WSi_{X}).

FIG. 2 is a cross-sectional view 200, corresponding to cross-sectional view 100 of FIG. 1, illustrating the wafer 10 is etched (wet etching) with the mask 20 functioning as a photomask on the wafer 10 by using an etchant gas 30 (after etching) according to some embodiments.

In some embodiments, the etchant gas 30 is selected from CF₄, CHF₃, NF₃, or the like, or a combination thereof. In some embodiments, the etchant gas 30 is CF₄. In some embodiments, the etchant gas 30 is CHF₃. In some embodiments, the etchant gas 30 is NF₃. In some embodiments, the etchant gas 30 is a combination of any of CF₄, CHF₃, NF₃, or the like.

At least partially metallic materials (such as WSiₓ) of the mask 20 can provide better etch resistance and allow for the use of gas chemistries that utilize more of leaner fluorocarbon (FC) or hydrofluorocarbon (HFC) gases (such as CHF₃, CF₄, and NF₃) that function as etchant gases. Working with such at least partially metallic materials (such as WSiₓ) of the mask 20, these leaner etch recipes may lead to higher etch rates and smaller contact deformation, while simultaneously maintaining satisfactory selectivity between the mask and the wafer that will be partially etched.

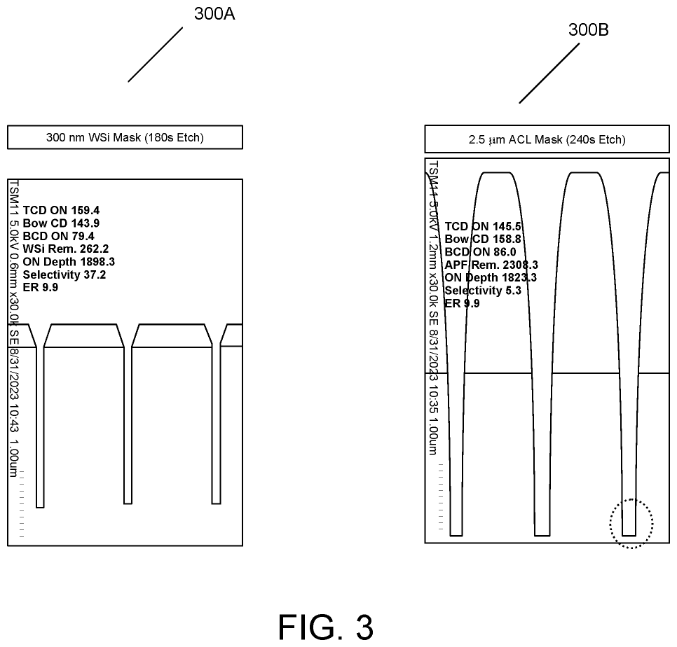

FIG. 3 illustrates a comparison of an etch of an ONO wafer with a WSix mask by using CHF₃ and NF₃ (leaner chemistries) as etchant gases as shown in 300A according to some embodiments and an etch of an ONO wafer with a traditional ACL mask by using C₄F₆ as an etchant gas as shown in 300B. Leaner chemistries such as CF₄, CHF₃, and NF₃ as applied according to some embodiments are not viable using the more etch-susceptible ACL mask. Experiment results illustrate that such leaner etch chemistry (such as using CHF₃ and NF₃ functioning as etchant gases) according to some embodiments shows feasibility for partial etching of an ONO layer with a WSiₓ mask, which can provide improved etch profile, faster etch rate, and better mask selectivity, compared to an etch of an ONO wafer with an ACL mask by using heavier chemistries (such as C₄F₆) as etchant gases.

It is noted that an etch of an ONO wafer with a WSix mask by using such leaner etch chemistry (such as CF₄, CHF₃, and NF₃) as etchant gases according to some embodiments can lead to greater selectivity compared to an etch of an ONO wafer with a traditional ACL mask by using heavier etch chemistries (such as C₄F₆) as an etchant gas. Leaner etch chemistries discussed herein contain no deposition-heavy FC gases (such as C₄F₆), which will reduce polymer-driven deformation, reduce profile bending with the WSix mask to maintain quality device performance with process integration, yield improved etch rate (ER), and consume less energy. For example, the selectivity of an etch of an ONO wafer with a WSix mask by using CHF₃ and NF₃ as etchant gases is 37.2, while the selectivity of an etch of an ONO wafer with an ACL mask by using C₄F₆ as an etchant gas is 8.7. For example, the ER of the etch of an ONO wafer with the WSix mask of 300 nm by using CHF₃ and NF₃ as etchant gases is 9.9, while the ER of the etch of an ONO wafer with the ACL mask of 2.5 μm by using C₄F₆ as the etchant gas is 8.8. A thinner mask can accelerate the etch rate compared to a thicker mask, and ACL can contribute some carbon-based deposition that can slow the etch rate. This carbon-based deposition can be avoided with the use of the WSix mask due to it being metal-based and containing no carbon intrinsically.

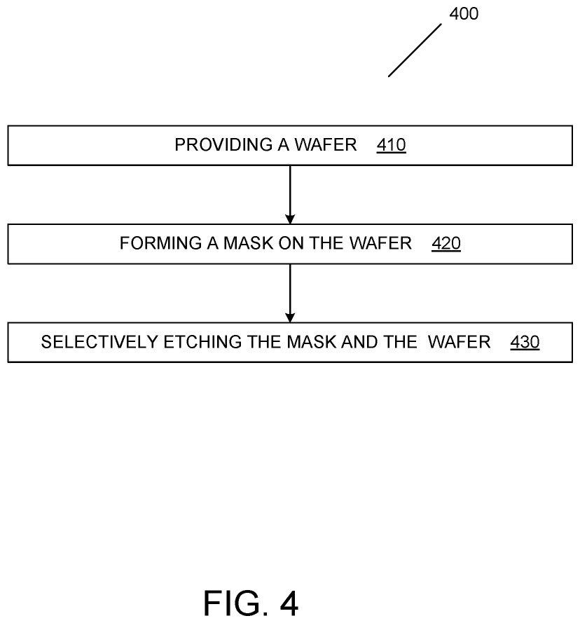

FIG. 4 is a flowchart illustrating a method 400 of etching a wafer 10 with a mask 20 by an etchant gas 30 corresponding to FIGS. 1 and 2 according to some embodiments. It is understood that additional operations can be provided before, during, and after processes discussed in FIG. 4, and some of the operations described below can be replaced or eliminated, for additional embodiments of the method. The order of the operations/processes may be interchangeable and at least some of the operations or processes may be performed in a different sequence.

Referring to FIGS. 1 and 4, in operation 410, a wafer 10 is provided. In some embodiments, the wafer 10 includes an oxide containing material layer. In some embodiments, the oxide containing material layer includes an oxide layer on a nitride layer (referred to as “ON” layers), and in other embodiments, the oxide containing material layer includes a stack of alternate oxide and nitride layers on top of each other (referred to as “ONO” layers).

Referring to FIGS. 1 and 4, in operation 420, a mask 20 having one or more patters is formed on the wafer 10. The patterns of the mask 20 can be formed by using, for example, photolithography, etching, and (chemical mechanical polishing) CMP processes, such that some regions of the top surface of the wafer 10 are exposed, while other regions of the top surface of the wafer 10 are covered and thus protected by the mask 20. In some embodiments, the mask 20 is a hard mask that includes a material at least partially containing metal. In some embodiments, the at least partially metallic material includes a tungsten containing material. In some embodiments, the tungsten containing material includes tungsten silicide (WSi_{X}).

Referring to FIGS. 2 and 4, in operation 430, the mask 20 and the wafer 10 under the mask 20 are selectively etched by using an etchant gas 30, thereby forming holes 40 with high aspect ratio into the wafer 10. In some embodiments, the etchant gas 30 is selected from CF₄, CHF₃, NF₃, or the like, or a combination thereof. In some embodiments, the etchant gas 30 is CF₄. In some embodiments, the etchant gas 30 is CHF₃. In some embodiments, the etchant gas 30 is NF₃. In some embodiments, the holes 40 with high aspect ratio are filled with conductive material such as Cu (not shown), thereby forming HARCs.

Due to the uses of the at least partially metallic material (such as WSix) as a material of the mask 20 and leaner etch chemistry (such as CF₄, CHF₃ and NF₃) as etchant gases 30 when etching an ON or ONO layer 10, etch profile is improved, etch selectivity between the mask 20 and the wafer 10 is increased, and the etch rate is also improved, thereby device yields and performances being highly improved.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims 1-20 and their equivalents, in which all terms are meant in their broadest reasonable sense unless otherwise indicated.

What is claimed is:

1. A method comprising:
providing a wafer, wherein the wafer comprises an oxide containing material layer;
forming a mask comprising at least a pattern on a surface of the wafer, wherein the mask comprises an at least partially metallic material; and
selectively etching the mask and the wafer under the mask by using an etchant gas, wherein the etchant gas is selected from a group consisting of CF₄, CHF₃, and NF₃.

2. The method of claim 1, wherein the oxide containing material layer comprises an oxide layer on a nitride layer.

3. The method of claim 1, wherein the oxide containing material layer comprises a stack of alternate oxide and nitride layers on top of each other.

4. The method of claim 1, wherein the at least partially metallic material comprises a tungsten containing material.

5. The method of claim 4, wherein the tungsten containing material comprises tungsten silicide (WSi_{X}).

6. An etchant for etching a wafer with a mask, comprising:
a gas selected from a group consisting of CF₄, CHF₃, and NF₃,
wherein the mask comprises at least a pattern and is made of an at least partially metallic material.

7. The etchant of claim 6, wherein the wafer comprises an oxide containing material layer.

8. The etchant of claim 7, wherein the oxide containing material layer comprises an oxide layer on a nitride layer.

9. The etchant of claim 7, wherein the oxide containing material layer comprises a stack of alternate oxide and nitride layers on top of each other.

10. The etchant of claim 6, wherein the at least partially metallic material comprises a tungsten containing material.

11. The etchant of claim 10, wherein the tungsten containing material comprises tungsten silicide (WSi_{X}).

12. A method comprising:
forming a mask comprising at least a pattern on a wafer, wherein the mask comprises an at least partially metallic material; and
selectively etching the mask and the wafer under the mask by using an etchant gas, wherein the etchant gas is selected from a group consisting of CF₄, CHF₃, and NF₃.

13. The method of claim 12, wherein the wafer comprises an oxide containing material layer.

14. The method of claim 13, wherein the oxide containing material layer comprises an oxide layer on a top of a nitride layer.

15. The method of claim 12, wherein the oxide containing material layer comprises a stack of alternate oxide and nitride layers on top of each other.

16. The method of claim 12, wherein the at least partially metallic material comprises a tungsten containing material.

17. The method of claim 16, wherein the tungsten containing material comprises tungsten silicide (WSi_{X}).

18. The method of claim 12, wherein the etchant gas consists of CF₄.

19. The method of claim 12, wherein the etchant gas consists of CHF₃.

20. The method of claim 12, wherein the etchant gas consists of NF₃.
